(19) United States
(12) Patent Application Publication
(10) Pub. No.: US 2026/0243934 A1
(43) Pub. Date: Aug. 20, 2026

(54) COLOR FILTER ARRAY AND DISPLAY DEVICE

(71) Applicant: E Ink Holdings Inc., HSINCHU (TW)

(72) Inventors: Po-Yuan LO, HSINCHU (TW); Wen-Heng HUANG, HSINCHU (TW); Ian FRENCH, HSINCHU (TW)

(21) Appl. No.: 19/417,340

(22) Filed: Dec. 12, 2025

Related U.S. Application Data
(60) Provisional application No. 63/760,087, filed on Feb. 18, 2025.

(51) Int. Cl. G02B 5/20; G02F 1/1335; H10D 86/60

(52) U.S. Cl. CPC G02B 5/201; G02F 1/133514; H10D 86/60

(57) ABSTRACT

A color filter array includes a first filter region, a second filter region, and a third filter region. The first filter region includes multiple first color resist regions having a first color. The second filter region includes multiple second color resist regions having a second color. The third filter region includes multiple third color resist regions having a third color. The first filter region includes at least one fourth color resist region, and the fourth color resist regions has the second color or the third color. The second filter region includes at least one fifth color resist region. The third filter region includes at least one sixth color resist region, and the fifth color resist region and the sixth color resist region include the first color.

CROSS - REFERENCE TO RELATED APPLICATION

This application claims priority to US Provisional Application Serial Number 63/760,087, filed February 18, 2025, which is herein incorporated by reference in its entirety.

### BACKGROUND

### Field of Invention

The present invention relates to a color filter array and a display device.

### Description of Related Art

In a color display device nowadays, each one of the filter regions of the color filter array corresponds to single pixel region or single thin film transistor. Such design makes the filter region without displaying shows obvious black stripes when the display device displays single color or two colors.

As an example, when the filter regions are distributed along a diagonal direction, obvious black stripes will affect the viewing experience and acceptability of the users when the display device displays single color or two colors. In addition, in a large-sized display device, such defects will be more prominent.

In view of this, how to provide a display device is still one of the goals that urgently need to be developed.

### SUMMARY

The invention provides a color filter array.

In one embodiment, the color filter array includes a first filter region, a second filter region, and a third filter region. The first filter region includes multiple first color resist regions having a first color. The second filter region includes multiple second color resist regions having a second color. The third filter region includes multiple third color resist regions having a third color. The first filter region includes at least one fourth color resist region, and the fourth color resist regions has the second color or the third color. The second filter region includes at least one fifth color resist region. The third filter region includes at least one sixth color resist region, and the fifth color resist region and the sixth color resist region include the first color.

Another aspect of the present disclosure is a display device.

In one embodiment, the display device includes a display region, a pixel array, and a color filter array. The display region includes multiple pixel regions, and each one of the pixel regions has a pixel area. The pixel array includes multiple thin film transistors, and the positions of the thin film transistors respectively correspond to the pixel regions of the display region. The color filter array is located on the pixel array. The color filter array includes multiple first filter regions, multiple second filter regions, and multiple third filter regions, wherein the first filter regions, the second filter regions, and the third filter regions each has a filter area, and the filter area is greater than the pixel area. Each one of the first filter regions includes a first main color resist region, each one of the second filter regions and the third filter regions include a first sub color resist region, and the first main color resist regions and the first sub color resist regions have the first color.

In the aforementioned embodiments, the influence from the black diagonal stripes in the display screen of a large-sized pixel can be reduced by transferring the color resists of each color to the filter regions with different colors in the color filter array of the display device in the present disclosure. Since each one of the filter regions, color resist regions of the display device encompass multiple pixel regions and multiple thin film transistors of the pixel array, the color resist transferring method can be determined by controlling the thin film transistors TFT based on the ratio and the pattern required.

### BRIEF DESCRIPTION OF THE DRAWINGS

The invention can be more fully understood by reading the following detailed description of the embodiment, with reference made to the accompanying drawings as follows:

FIG. 1 is a cross-sectional view of a display device according to one embodiment of the present embodiment.

FIG. 2 is a top view of a color filter array according to one embodiment of the present embodiment.

FIG. 3 is an enlarged view of the color filter array in FIG. 1.

FIG. 4 is a schematic diagram when the color filter array showing single color according to one embodiment of the present embodiment.

FIG. 5 is a top view of a color filter array according to another embodiment of the present embodiment.

FIG. 6 is an enlarged view of the color filter array in FIG. 5.

FIG. 7 is a schematic diagram when the color filter array showing single color according to one embodiment of the present embodiment.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

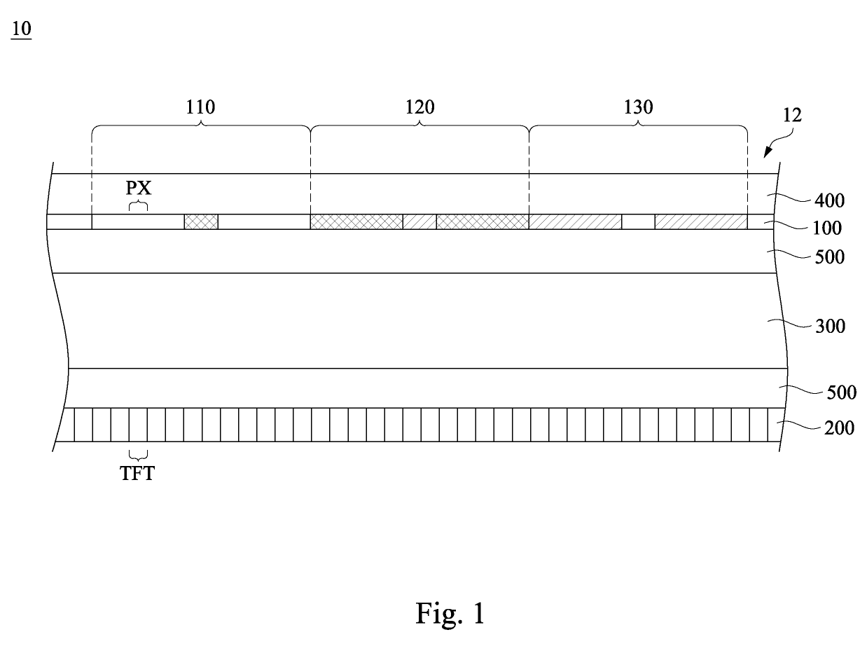

FIG. 1 is a cross-sectional view of a display device 10 according to one embodiment of the present embodiment. The display device 10 includes a color filter array 100, a pixel array 200, and a display medium layer 300. The color filter array 100 and the display medium layer 300 are adhered through an adhesive layer 500. The display medium layer 300 and the pixel array 200 are adhered through an adhesive layer 500. The cover 400 is disposed on the color filter array 100, such as transparent substrate.

The display device 10 of the present disclosure is a large-sized advertising signboard, used for a visual distance up to several meters. According to an equation that the visual distance equals pixel pitch divided by the resolution angle, it can be derived that the pixel pitch is about 2 millimeters.

The display device 10 includes a display region 12. The position of the pixel array 200 corresponds to the display region 12. The range of the display region 12 encompasses multiple pixel regions PX. Each one of the pixel regions PX has a pixel area. Each pixel regions PX respectively corresponds to the thin film transistors TFT of the pixel array 200. Therefore, the color displayed by each of the pixel regions PX can be controlled independently by the thin film transistors TFT.

The color filter array 100 is located on the pixel array 200. The color filter array 100 includes first filter region 110, second filter regions 120, and third filter regions 130. The first filter regions 110, the second filter regions 120, and the third filter regions 130 each has the same filter area. The filter areas are greater than the pixel area. In other words, the color filter array 100 of the present disclosure has large-sized pixel (e.g., 2.042 millimeters). Each of the filter regions encompasses multiple thin film transistors TFT of the pixel array 200. As such, the black stripes along a diagonal direction can be eliminated through adjusting the color arrangement of each pixel regions in the large-sized filter region.

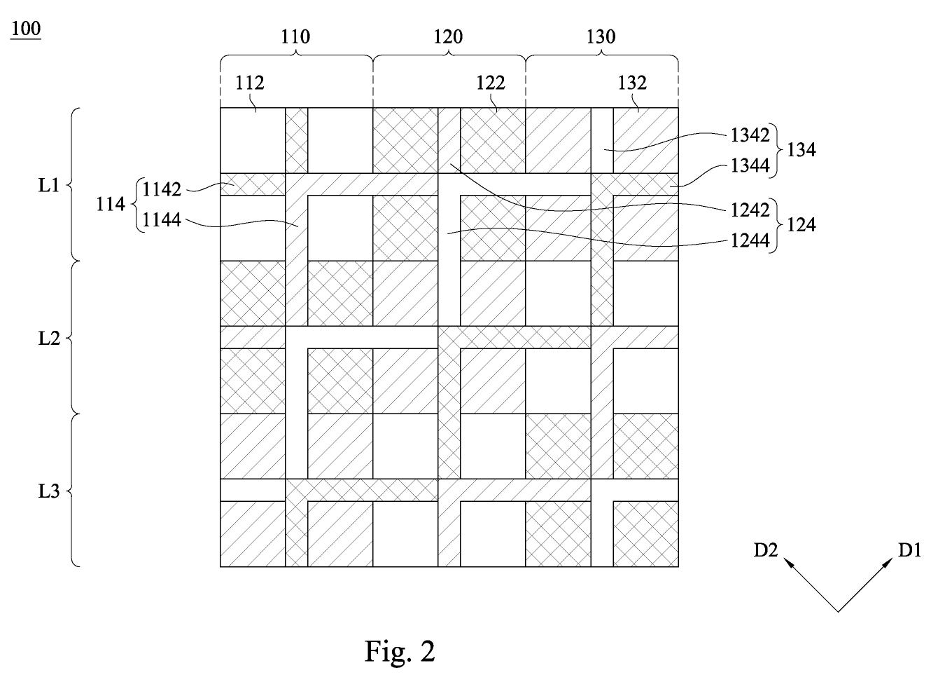

FIG. 2 is a top view of a color filter array 100 according to one embodiment of the present embodiment. A first row L1 of the color filter array 100 is used as an example, and the first filter regions 110 include multiple first color resist regions 112. The first color resist regions 112 have a first color. The first color in the first row L1 is, for example, green color. The second filter regions 120 include multiple second color resist regions 122. The second color resist regions 122 have a second color. The second color in the first row L1 is, for example, blue color. The third filter regions 130 include multiple third color resist regions 132. The third color resist regions 132 have a third color. The third color in the first row L1 is, for example, red color. The first color resist regions 112, the second color resist regions 122, and the third color resist regions 132 both have four rectangular regions divided by a cross-shaped region, but the present disclosure is not limited thereto.

The first filter regions 110 include at least one fourth color resist region 114. The fourth color resist regions 114 have a color other than the first color, which is the blue color or red color. In other words, the first color resist regions 112 and the fourth color resist regions 114 have different color. In the present embodiment, the fourth color resist regions 114 respectively include a first portion 1142 having the blue color and a second portion 1144 having the red color. In the present embodiment, the first portion 1142 and the second portion 1144 are respectively located at the left-upper half part and the left-lower half part of the first filter regions 110, but the present disclosure is not limited thereto.

The second filter regions 120 include at least one fifth color resist region 124, and the fifth color resist regions 124 has a color other than the second color, that is the green color or red color. In other words, the second color resist regions 122 and the fifth color resist regions 124 have different color. In the present embodiment, the fifth color resist regions 124 respectively include a first portion 1242 having the red color and a second portion 1244 having the green color. In the present embodiment, the first portion 1242 and the second portion 1244 are respectively located at the left-upper half part and the left-lower half part of the second filter regions 120, but the present disclosure is not limited thereto.

The third filter regions 130 include at least one sixth color resist region 134, and the sixth color resist regions 134 has a color other than the third color, that is the blue color or green color. In other words, the third color resist regions 132 and the sixth color resist regions 134 have different color. In the present embodiment, the sixth color resist regions 134 respectively include a first portion 1342 having the green color and a second portion 1344 having the blue color. In the present embodiment, the first portion 1342 and the second portion 1344 are respectively located at the left-upper half part and the left-lower half part of the third filter regions 130, but the present disclosure is not limited thereto.

An area of the first color resist regions 112 is greater than an area of the fourth color resist regions 114. In other words, the first color resist regions 112 having the first color (green) are the main color source of the first filter regions 110, and the fourth color resist regions 114 are the subordinate color source of the first filter regions 110. The areas of the first color resist regions 112 and the fourth color resist regions 114 are greater than the pixel area. In other words, each one of the first color resist regions 112 and the fourth color resist regions 114 encompass multiple thin film transistors TFT of the pixel array 200, and therefore the pattern and the arrangement method are adjustable.

An area of the second color resist regions 122 is greater than an area of the fifth color resist regions 124. In other words, the second color resist regions 122 having the second color (blue) are the main color source of the second filter regions 120, and the fifth color resist regions 124 are the subordinate color source of the second filter regions 120. The areas of the second color resist regions 122 and the fifth color resist regions 124 are greater than the pixel area. In other words, each one of the second color resist regions 122 and the fifth color resist region 124 encompass multiple thin film transistors TFT of the pixel array 200, and therefore the pattern and the arrangement method are adjustable.

An area of the third color resist regions 132 is greater than an area of the sixth color resist regions 134. In other words, the third color resist regions 132 having the third color (red) are the main color source of the third filter regions 130, and the sixth color resist regions 134 are the subordinate color source of the third filter regions 130. The areas of the third color resist regions 132 and the sixth color resist regions 134 are greater than the pixel area. In other words, the third color resist regions 132 and the sixth color resist regions 134 encompass multiple thin film transistors TFT of the pixel array 200, and therefore the pattern and the arrangement method are adjustable.

In the second row L2 of the color filter array 100, the filter regions from the left to the right are respectively the second filter region 120 (blue), the third filter region 130 (red), and the first filter region 110 (green) the same as those in the first row L1. In the third row L3, the filter regions from the left to the right are respectively the third filter region 130 (red), the first filter region 110 (green), and the second filter region 120 (blue) the same as those in the first row L1. In other words, the first filter regions 110, the second filter regions 120, and the third filter regions 130 are respectively arranged along the first diagonal direction D1.

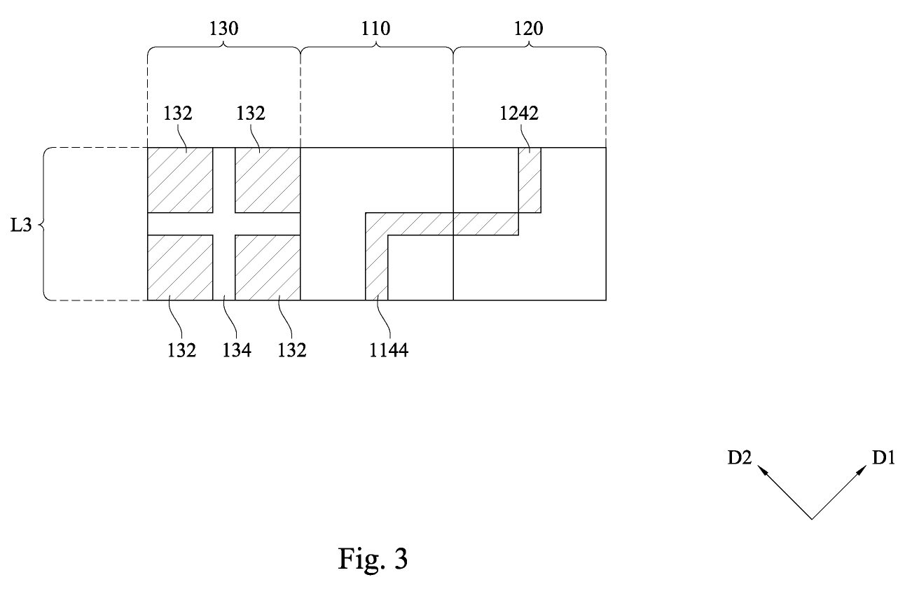

FIG. 3 is an enlarged view of the color filter array 100 in FIG. 1. Merely the third color resist region 132, the second portion 1144 of the fourth color resist region 114, and the first portion 1242 of the fifth color resist region 124 in the third row L3 which contain the red color of the color filter array 100 are illustrated in FIG. 3.

A sum of the areas of third color resist region 132, the second portion 1144 of the fourth color resist region 114, and the first portion 1242 of the fifth color resist region 124 is equal to a first area of the first filter region 110. In other words, this design is equivalent to transferring the red color resist filled in the third filter region 130 to the second filter region 120 and the first filter region 110 which having the blue color and the green color. Since the third color resist region 132, the fourth color resist region 114, and the fifth color resist region 124 all encompass multiple pixel regions PX and multiple thin film transistors TFT of the pixel array 200, and therefore the color resist transferring method can be determined by controlling the thin film transistors TFT based on the ratio and the pattern required. In the present embodiment, the second portion 1144 of the fourth color resist region 114 and the first portion 1242 of the fifth color resist region 124 have different patterns.

The same color resist transferring design can be employed to the first color resist region 112, the second portion 1244 of the fifth color resist region 124, and the first portion 1342 of the sixth color resist region 134 which have the green color shown in FIG. 1. The same color resist transferring design can be employed to the second color resist region 122, the first portion 1142 of the fourth color resist region 114, and the second portion 1344 of the sixth color resist region 134 which have the blue color. Therefore, a sum of the areas of the color resists with the same color is constant, and therefore the white balance of the display device 10 will not be affected by the color resist transferring design.

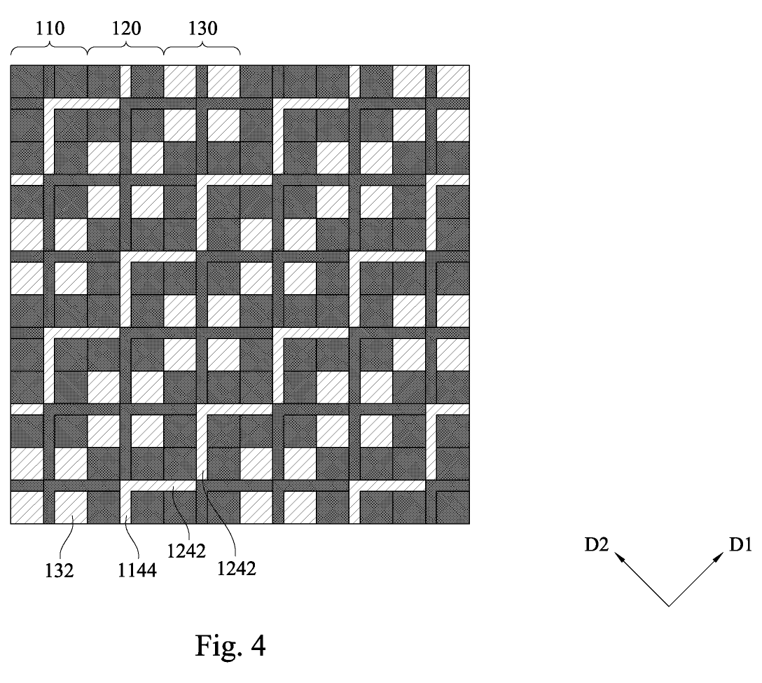

FIG. 4 is a schematic diagram when the color filter array showing single color according to one embodiment of the present embodiment. In the present embodiment, a third filter region 130 that shows red color is used as an example. In a range corresponding to the first filter region 110 (green) and the second filter region 120 (blue), the transferred color resists (that is, the second portion 1144 of the fourth color resist region 114 and the first portion 1242 of the fifth color resist region 124 that are red) are ladder-shaped and extend along the first diagonal direction D1. In the present embodiment, the second portion 1144 of the fourth color resist region 114 and the first portion 1242 of the fifth color resist region 124 are respectively symmetrical relative to the second diagonal direction D2, but the present disclosure is not limited thereto. Since the red color resists are transferred to the region which is originally displayed as black, the black stripes become less visible. As such, the influence from the black diagonal stripes in the display screen of a large-sized pixel can be reduced.

Reference is made to FIG. 2. Alternatively speaking, each one of the first filter regions 110 includes a main color resist region (that is the first color resist region 112), and the second filter region 120 includes a first subordinate color resist region (that is the second portion 1244 of the fifth color resist region 124), and the third filter region 130 also includes a first subordinate color resist region (that is the first portion 1342 of the sixth color resist region 134), and the first main color resist region and the first subordinate color resist regions are all have the green color. Areas of the first main color resist region and the first subordinate color resist regions are greater than the pixel area.

Similarly, each one of the second filter regions 120 includes a main color resist region (that is the second color resist region 122), the first filter region 110 includes a second subordinate color resist region (that is the first portion 1142 of the fourth color resist region 114), and the third filter region 130 includes a second subordinate color resist region (that is the second portion 1344 of the sixth color resist region 134), and the second main color resist region and the second subordinate color resist regions are all have the blue color. Areas of the second main color resist region and the second subordinate color resist regions are greater than the pixel area.

Similarly, each one of the third filter regions 130 includes a main color resist region (that is the third color resist region 132), and the first filter region 110 includes a third subordinate color resist region (that is the second portion 1144 of the fourth color resist region 114), the second filter region 120 includes a third subordinate color resist region (that is the first portion 1242 of the fifth color resist region 124), and the third main color resist region and the third subordinate color resist regions are all red. Areas of the third main color resist region and the third subordinate color resist regions are greater than the pixel area.

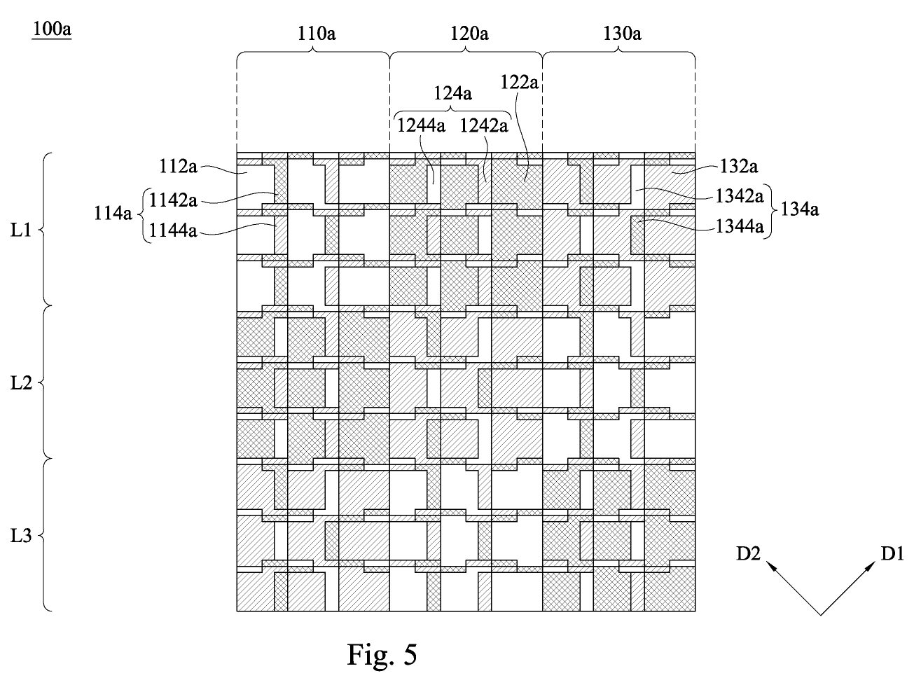

FIG. 5 is a top view of the color filter array 100a according to another embodiment of the present embodiment. The color filter array 100a is similar to the color filter array 100 shown in FIG. 2, and the difference is the pattern and the arrangement of the color resist regions.

In the present embodiment, the first color resist regions 112a of the first filter region 110a is substantially divided as at least nine sections by the fourth color resist regions 114a, and the nine sections have different sizes and shapes. The fourth color resist regions 114a include first portions 1142a having the blue color and second portions 1144a having the red color. The positions of the first portions 1142a and the second portions 1144a are alternatively distributed, but the present disclosure is not limited thereto. As described above, the area of the first color resist 112a is greater than the area of the fourth color resist regions 114a.

The second color resist regions 122a of the second filter region 120a is substantially divided as at least nine sections by the fifth color resist region 124a, and the nine sections have different sizes and shapes. The fifth color resist regions 124a include first portions 1242a having the red color and second portions 1244a having the green color. The positions of the first portions 1242a and the second portions 1244a are alternatively distributed, but the present disclosure is not limited thereto. As described above, the area of the second color resist 122a is greater than the area of the fifth color resist regions 124a.

The third color resist regions 132a of the third filter region 130a is substantially divided as at least nine sections by the sixth color resist region 134a, and the nine sections have different sizes and shapes. The sixth color resist regions 134a include first portions 1342a having the green color and a second portions 1344a having the blue color. The positions of the first portions 1342a and the second portions 1344a are alternatively distributed, but the present disclosure is not limited thereto. As described above, the area of the third color resist 132a is greater than the area of the sixth color resist regions 134a.

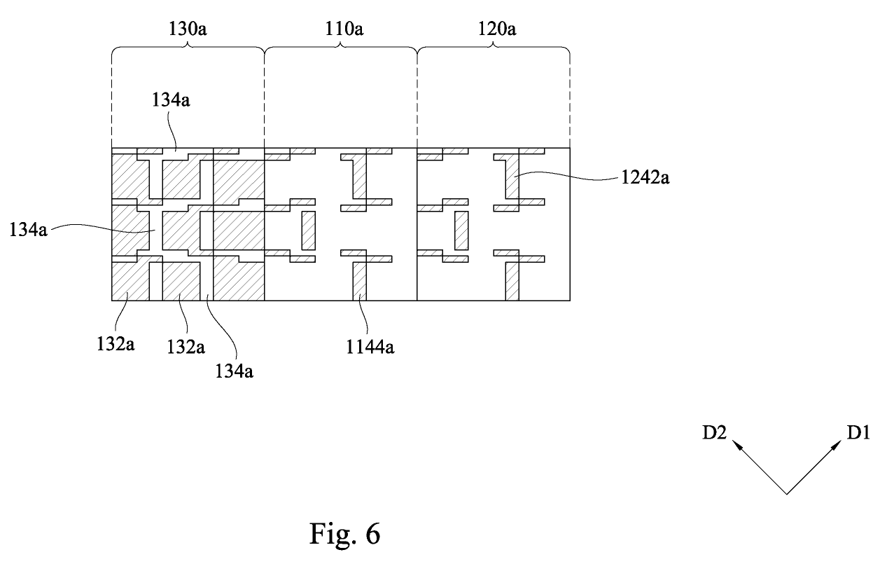

FIG. 6 is an enlarged view of the color filter array 100a in FIG. 5. Merely the third color resist region 132a, the second portions 1144a of the fourth color resist region 114a, and the first portions 1242a of the fifth color resist region 124a which contain red color in the third row L3 of the color filter array 100a are illustrated in FIG. 6. In the present embodiment, the second portions 1144a of the fourth color resist region 114a and the first portions 1242a of the fifth color resist region 124a have the same pattern.

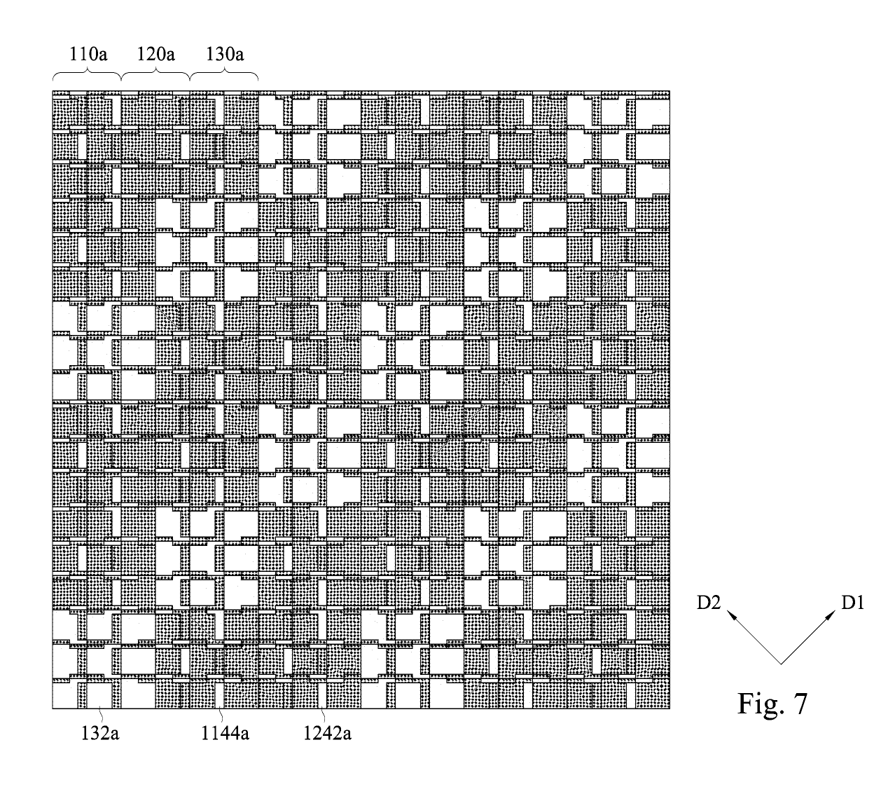

FIG. 7 is a schematic when the color filter array showing single color according to one embodiment of the present embodiment. In the present embodiment, a third filter region 130 that shows red is used as an example. In a range corresponding to the first filter region 110a (green) and the second filter region 120a (blue), the transferred red color resists (that is, the second portions 1144a of the fourth color resist region 114a and the first portions 1242a of the fifth color resist region 124a that are red) are distributed. Since the red color resists are transferred to the region which is originally displayed as black, the black stripes become less visible. As such, the influence from the black diagonal stripes in the display screen of a large-sized pixel can be reduced.

In summary, the influence from the black diagonal stripes in the display screen of a large-sized pixel can be reduced by transferring the color resists of each colors to the filter regions with different colors in the color filter array of the display device in the present disclosure. Since each one of the filter regions, color resist regions of the display device encompass multiple pixel regions and multiple thin film transistors of the pixel array, the color resist transferring method can be determined by controlling the thin film transistors TFT based on the ratio and the pattern required.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A color filter array, comprising:
a first filter region comprising a plurality of first color resist regions, wherein the first color resist regions have a first color;
a second filter region comprising a plurality of second color resist regions, wherein the second color resist regions have a second color; and
a third filter region comprising a plurality of third color resist regions, wherein the third color resist regions have a third color; wherein
the first filter region comprises at least one fourth color resist region, and the fourth color resist regions has the second color or the third color, the second filter region comprises at least one fifth color resist region, the third filter region comprises at least one sixth color resist region, and the fifth color resist region and the sixth color resist region have the first color.

2. The color filter array of claim 1, wherein an area of the first color resist regions is greater than an area of the fourth color resist region.

3. The color filter array of claim 1, wherein an area of the second color resist regions is greater than an area of the fifth color resist region.

4. The color filter array of claim 1, wherein an area of the third color resist regions is greater than an area of the sixth color resist region.

5. The color filter array of claim 1, wherein a number of the at least one fourth color resist region is plural, and the fourth color resist regions comprise a first portion having the second color and a second portion having the third color.

6. The color filter array of claim 1, wherein a number of the at least one fifth color resist region is plural, and the fifth color resist regions comprise a first portion having the third color and a second portion having the first color.

7. The color filter array of claim 1, wherein a number of the at least one sixth color resist region is plural, and the sixth color resist regions comprise a first portion having the first color and a second portion having the second color.

8. The color filter array of claim 1, wherein a sum of the areas of the fifth color resist region having the first color, the sixth color resist region, and the first color resist region is equal to a filter area of the first filter region.

9. The color filter array of claim 1, wherein the at least one fourth color resist region and the at least one sixth color resist region further comprise the second color, and a sum of the areas of the fourth color resist region, the sixth color resist region, and the second color resist region having the second color is equal to a filter area of the second filter region.

10. The color filter array of claim 1, wherein the at least one fourth color resist region and the at least one fifth color resist region further comprise the third color, and a sum of the areas of the fourth color resist region, the fifth color resist region, and the third color resist region having the third color is equal to a filter area of the third filter region.

11. A display device, comprising:
a display region comprising a plurality of pixel regions, wherein each one of the pixel regions has a pixel area;
a pixel array comprising a plurality of thin film transistors, and the positions of the thin film transistors respectively correspond to the pixel regions of the display region; and
a color filter array located on the pixel array, wherein the color filter array comprises a plurality of first filter regions, a plurality of second filter regions, and a plurality of third filter regions, wherein the first filter regions, the second filter regions, and the third filter regions each has a filter area, and the filter area is greater than the pixel area, wherein
each one of the first filter regions comprises a first main color resist region, each one of the second filter regions and the third filter regions comprises a first sub color resist region, and the first main color resist region and the first sub color resist regions have a first color.

12. The display device of claim 11, wherein the area of the first main color resist region and the first sub color resist regions are greater than the pixel area.

13. The display device of claim 11, wherein the area of the first main color resist region is greater than the areas of the first sub color resist regions.

14. The display device of claim 11, wherein each one of the second filter regions comprises a second main color resist region, each one of the first filter regions and the third filter regions comprises a second sub color resist region, and the second main color resist region and the second sub color resist regions have a second color.

15. The display device of claim 14, wherein the areas of the second main color resist region and the second sub color resist regions are greater than the pixel area.

16. The display device of claim 14, wherein the area of the second main color resist regions is greater than the areas of the second sub color resist regions.

17. The display device of claim 11, wherein each one of the third filter regions comprises a third main color resist region, each one of the first filter regions and the second filter regions comprises a third sub color resist region, and the third main color resist region and the third sub color resist regions have a third color.

18. The display device of claim 17, wherein the areas of the third main color resist region and the third sub color resist regions are greater than the pixel area.

19. The display device of claim 17, wherein the area of the third main color resist region are greater than the areas of the third sub color resist regions.

20. The display device of claim 18, wherein the first sub color resist regions are symmetrical relative to a diagonal direction.
